(19) United States
(12) Patent Application Publication
(10) Pub. No.: US 2005/0160982 A1
(43) Pub. Date: Jul. 28, 2005

(54) Plasma enhanced semicondutor deposition apparatus

(76) Inventors: Min-no Ha, Suwon-si (KR); Jin-Ho Jeon, Yeongtong-gun (KR); Yi-Ha Jeong, Suwon-si (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/000,942

(22) Filed: Dec. 2, 2004

(30) Foreign Application Priority Data
Jan. 27, 2004 (KR) 2004-05085

(51) Int. Cl. C23C 16/00

(52) U.S. Cl. 118/715

(57) ABSTRACT

A plasma enhanced chemical vapor deposition apparatus includes a process chamber, and at least one gas injection pipe extending within the process chamber. Each gas injection pipe has an injection region from which source gases are injected through the sidewall of the pipe into the process chamber. To this end, a plurality of slots are located in the injection region. The slots minimize the likelihood that the source gas will be converted to plasma within the gas injection pipe. Accordingly, particle contamination can be minimized.

### BACKGROUND OF THE INVENTION

1. Field of the Invention

The present invention generally relates to apparatus for fabricating semiconductor devices. More specifically, the present invention relates to a plasma enhanced semiconductor deposition apparatus.

2. Description of the Related Art

In the fabricating of semiconductor devices, semiconductor deposition apparatus are used to deposit material on wafers, these wafers being the substrates of the semiconductor devices. Included among the semiconductor deposition apparatus are chemical vapor deposition apparatus which deposit material using source gases that facilitate chemical reactions.In general, chemical vapor deposition apparatus mainly use thermal energy in inducing the chemical reactions of the source gases. Accordingly, when a semiconductor device fabrication process is performed using a chemical vapor deposition apparatus, the temperature at which the process is being carried out tends to rise. Plasma Enhanced Chemical Vapor Deposition (PE-CVD) apparatus have been used to keep the process temperature relatively low during the deposition process.

Plasma chemical vapor deposition apparatus use the energy from plasma as well as thermal energy to excite the source gases. Thus, it is possible to use less thermal energy for exciting the source gases. Therefore, the process temperature can be kept relatively low.

FIG. 1 schematically shows constituent elements of a conventional plasma chemical vapor deposition apparatus. FIG. 2 shows a gas injection pipe of the conventional chemical vapor deposition apparatus shown in FIG. 1. FIG. 3 is a cross-sectional view of the gas injection pipe taken along line I-I′ of FIG. 2. Referring to FIGS. 1, 2 and 3, a plasma chemical vapor apparatus includes a process chamber in which a deposition process is performed. An electrostatic chuck 1 is disposed in the process chamber. The electrostatic chuck 1 is adapted to support and hold a wafer W in place. A plurality of gas injection pipes 2 extend into the process chamber for injecting source gases in the process chamber. To this end, the gas injection pipes 2 are connected to an external gas supplier (not shown). One end of each gas injection pipe 2 defines a circular injection nozzle 3 oriented towards the wafer W. The plasma chemical vapor deposition apparatus also includes a plasma generating means (not shown) capable of generating plasma in the process chamber.

A process for depositing material on the wafer W using the plasma chemical vapor deposition apparatus will be described hereinafter. First, the wafer W is loaded on the electrostatic chuck 1. Then, power is supplied to the plasma generating means for generating plasma. A bias is applied to the electrostatic chuck 1.Subsequently, source gases flowing as a stream 5 through an internal passageway of the injection pipe 2 are injected towards the wafer W via the injection nozzle 3. The injected source gases are converted to plasma over the electrostatic chuck 1 by the plasma generating means. The plasma is attracted to the wafer W by the bias applied to the electrostatic chuck 1, thereby forming a layer of material on the wafer W.

However, a residue 4 of the material may be formed in the gas injection pipe 2 around the circular injection nozzle 3 while the deposition process is taking place. More specifically, when source gases are injected through the injection pipe 2 in the process chamber, power is being supplied to the process chamber by the plasma generating means. The source gases are converted to plasma by this power. The power may be supplied to the gas injection pipe 2 and concentrate at the circular injection nozzle 3. Accordingly, source gases may be converted to plasma in the gas injection pipe 2 before they are injected through the injection nozzle 3. As a result, the residue 4 may be formed in the gas injection pipe 2.

The residue 4 in the gas injection pipe 2 becomes a source of particle contamination for the wafer W. That is, as source gases are injected in the process chamber, the residue 4 may be entrained by the source gases and injected in the process chamber. Accordingly, the residue 4 drops on the wafer W, thereby contaminating the wafer W. As a result, the semiconductor devices become defective. In addition, the chemical vapor deposition apparatus must be cleaned frequently to remove the residue 4 and thereby prevent the wafers W from being contaminated. Accordingly, the productivity of the deposition process is lowered.

### SUMMARY OF THE INVENTION

An object of the present invention is to provide a plasma chemical vapor deposition apparatus capable of minimizing particle contamination.

According to one aspect of the present invention, there is provided a plasma chemical vapor deposition apparatus including a process chamber, an electrostatic chuck disposed in the process chamber, and at least one gas injection pipe extending into the process chamber, wherein the injection region of the gas injection pipe is formed by a plurality of slots extending through the sidewall of the pipe.

Thus, each injection slot has an inlet contiguous with the internal passageway of the gas injection pipe, and an outlet that defines an opening at the exterior of the sidewall of the pipe. Preferably, the width of the injection slot gradually increases from the inlet to the outlet thereof. Also, the injection slots preferably radiate from a central area of the injection region. Even more preferably, the injection slots are disposed equi-angularly about the central portion of the injection region. In these cases, the width of each injection slot may gradually increase from one end of the injection slot to the other end of the injection slot.

The gas injection pipe may also have a plurality of injection holes extending through the sidewall of the pipe at the central area of the injection region. Thus, each of the injection holes has an inlet contiguous with the internal passageway of the gas injection pipe, and an outlet that defines an opening at the exterior of the sidewall of the pipe. Preferably, the width of the injection hole gradually increases from the inlet to the outlet thereof. The injection holes may include a central injection hole disposed at the center of the central area of the injection region, and a plurality of peripheral injection holes each disposed along one of a plurality of circles whose centers coincide with the center at the central injection hole. In this case, the central injection hole and peripheral injection holes may be arranged in groups in which the injection holes are aligned along a respective direction extending diametrically with respect to the circles. In each of these groups, the peripheral injection holes may be inclined inwardly in directions toward the central injection hole. Outer ones of the peripheral injection holes, as taken in the diametrical direction, are preferably inclined to a greater degree than inner ones of the peripheral injection holes.

### BRIEF DESCRIPTION OF THE DRAWINGS

FIG. 1 is a schematic diagram of constituent elements of a conventional plasma chemical vapor deposition apparatus.

FIG. 2 is a bottom view of a gas injection pipe of the conventional plasma chemical vapor deposition apparatus.

FIG. 3 is a cross-sectional view of the gas injection pipe as taken along line I-I′ of FIG. 2.

FIG. 4 is a cross-sectional view a plasma chemical vapor deposition apparatus according to the present invention.

FIG. 5 is a plan view of the plasma chemical vapor deposition apparatus according to the present invention.

FIG. 6 is a bottom view of an end of the gas injection pipe employed by the apparatus of FIG. 5.

FIG. 7 is a plan view of an injection slot of the gas injection pipe shown in FIG. 6.

FIG. 8 is a cross-sectional view of the injection slot taken along line II-II′ of FIG. 7.

FIG. 9 is a plan view of a central portion of the injection region of the gas injection pipe shown in FIG. 6.

FIG. 10 is a cross-sectional view of the central portion of the injection region taken along line III-III′ of FIG. 9.

FIG. 11 is a bottom view of an end of another embodiment of a gas injection pipe employed by the apparatus of FIG. 5.

FIG. 12 is a plan view of an injection slot of the gas injection pipe shown in FIG. 11.

FIG. 13 is a cross-sectional view of the injection slot taken along line IV-IV′ of FIG. 12.

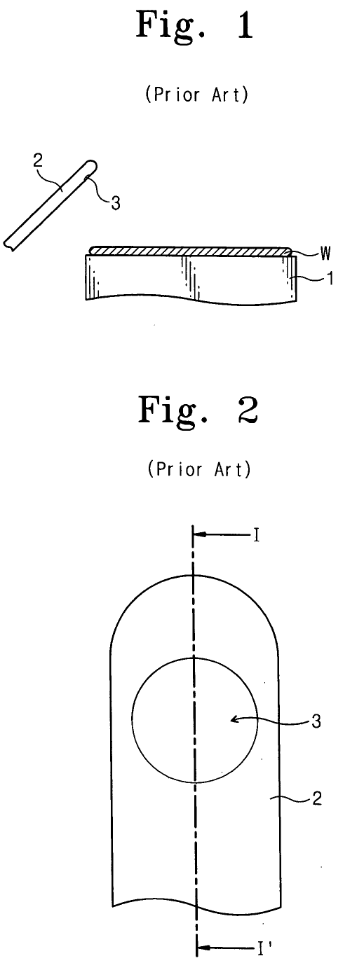

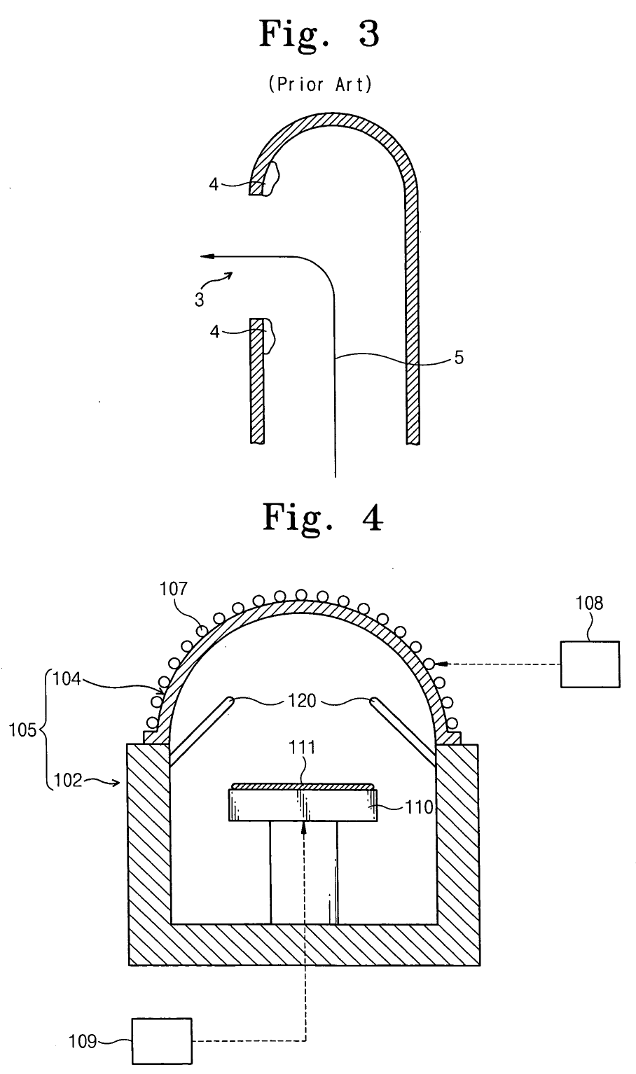

### DETAILED DESRIPTION OF THE PREFERRED EMBODIMENTS

The present invention will be described more fully hereinafter with reference to the accompanying drawings. Note, like numbers are used to designate like elements throughout the drawings.

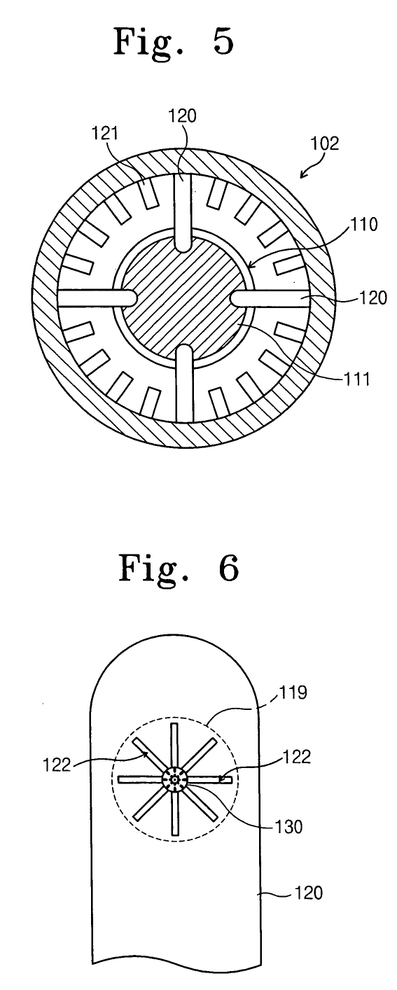

Referring first to FIGS. 4 and 5, a plasma chemical vapor deposition apparatus according to the present invention includes a process chamber 105 and an electrostatic chuck 110 disposed in the process chamber 105. A deposition process is performed in the process chamber 105 on a wafer 111 supported by the electrostatic chuck 110. The process chamber 105 has an upper portion 102 and a lower portion 104. The upper portion 102 may have the form of a dome. A plasma generating means 107 is disposed on an external wall surface of the upper portion 102 of the process chamber 105. The plasma generating means 107 may comprise a coil which winds around the upper portion 102 of the process chamber 105 many times.

The plasma generating means 107 is connected to a first generator 108, and the electrostatic chuck 110 is connected to a second generator 109. The first and second generators 108 and 109 generate first and second radio frequency powers, respectively. The first radio frequency power is supplied to the plasma generating means 107 to facilitate the generation of plasma in the process chamber 105. The second radio frequency power is supplied to the electrostatic chuck 110 to induce the plasma to flow to the electrostatic chuck 110. The first radio frequency power may have a frequency lower than that of the second radio frequency power. At least one gas injection pipe 120 extends into the process chamber 105. The gas injection pipe 120 is connected to a gas supplier disposed outside the process chamber 105. The gas injection pipe 120 may extend over the electrostatic chuck 110. The plasma chemical vapor deposition apparatus may further include a plurality of subsidiary injection pipes 121 extending into the process chamber 105, in order to more uniformly inject source gases onto the wafer 111. The subsidiary injection pipes 121 have a subsidiary injection nozzle for injecting source gases. The parts of the subsidiary injection pipes 121 that are located in the process chamber may be shorter than the parts of the gas injection pipes 120 that are located in the process chamber 105.

The gas injection pipes 120 will now be more fully described referring to FIGS. 6 to 10. Each gas injection pipe 120 has an injection region 119 at a predetermined portion of the sidewall thereof located within the process chamber 105. As shown in FIG. 6, the injection region 119 may be round. However, the injection region 119 may have another shape such as that of a polygon. The injection region 119 may have the same area as that of a conventional injection nozzle.

In any case, a plurality of injection slots 122 are located within the injection region 119. Each injection slot 122 extends through the sidewall of the pipe 120 so as to place an internal passageway of the gas injection pipe 120 in communication with the interior of the process chamber 105. That is, the injection slots 122 constitute nozzles for injecting source gases into the process chamber 105. Preferably, the injection slots 122 radiate from a central area 130 of the injection region 119. In this case, the injection slots 122 are preferably disposed equi-angularly about the central portion 130 of the injection region 119.

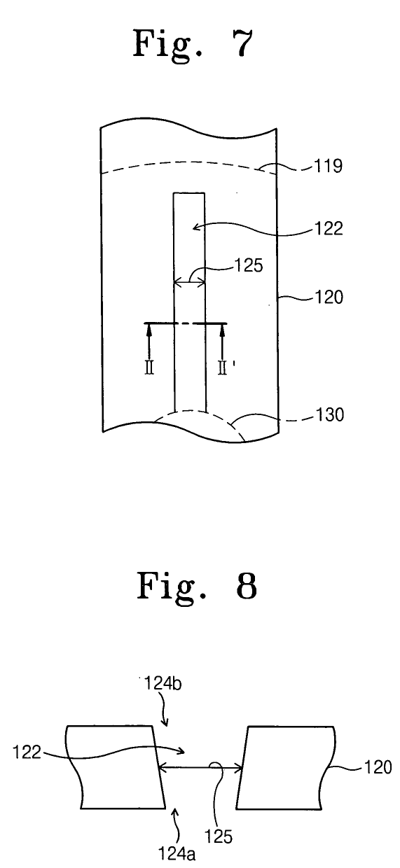

As best shown in FIGS. 7 and 8, each injection slot 122 has a slot width 125. The slot width is the distance between opposing wall surfaces of the pipe 120 that define sidewalls of the injection slot 122. The slot width 125 may be uniform from one end of the injection slot 122 to the other end of the injection slot 122 (FIG. 7). Also, each injection slot 122 has a slot inlet 124a and a slot outlet 124b (FIG. 8). The slot inlet 124a is contiguous with the internal passageway of the gas injection pipe 120. The slot outlet 124b forms an opening at the outside of the gas injection pipe 120, i.e., opens directly to the interior of the process chamber 105. Source gases flowing along the internal passageway of the gas injection pipe 120 enter the slot inlet 124a and are injected into the process chamber via the slot outlet 124b. Preferably, the slot width 125 gradually increases from the slot inlet 124a to the slot outlet 124b. In other words, the opposing wall surfaces of the pipe that define the sidewalls of the injection slot 120 are sloped such that the slot inlet 124a is narrower than the slot outlet 124b. The width of the slot inlet 124a is preferably 0.8 mm to 3 mm.

The magnitude of the power—supplied to generate plasma within the process chamber 105—is rather low within the gas injection pipe 120 because the narrow injection slots 122 constitute the injection region 119. In other words, the areas of communication between the internal passageway of the gas injection pipe 120 and the interior of the process chamber 105 are narrower than the area of communication between the internal passageway of the conventional injection pipe and the interior of a conventional process chamber. As a result, a minimal amount of residue is produced within the gas injection pipe 120 at the injection region 119.

Additionally, the injection slots 122 extend radially from the central area 130 of the injection region 119. Accordingly, source gases are uniformly injected through the injection slots 122 over a wafer 111 supported on the electrostatic chuck 1. Moreover, the width 125 of the injection slot 122 gradually increases from the slot inlet 124a to the slot outlet 124b. Therefore, the uniformity of the injection of the source gases is enhanced.

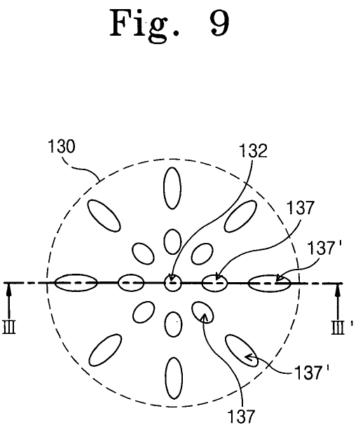

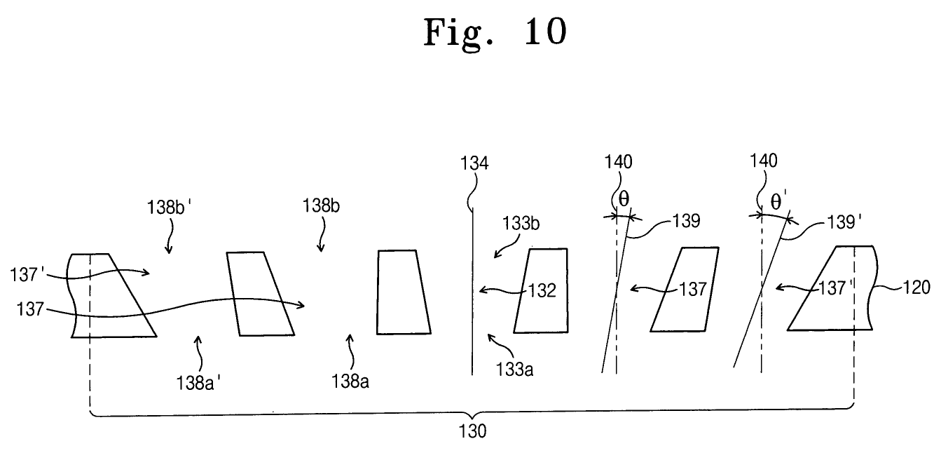

Referring now to FIGS. 9 and 10, preferably, a plurality of injection holes 132, 137 and 137′ are located at the central portion 130 of the injection region 119. The injection holes 132, 137 and 137′ extend through the gas injection pipe 120 so as to place the internal passageway of the gas injection pipe 120 in communication with the interior of the process chamber 105. Accordingly, the source gases are injected into the process chamber 105 via the injection holes 132, 137 and 137′ as well as through the injection slots 122. That is, the injection holes 132, 137 and 137′ allow for a greater amount of the source gases to be injected into the process chamber 105.

The injection holes 132, 137 and 137′ may include a central injection hole 132 and a plurality of peripheral injection holes 137 and 137′. The central injection hole 132 is located at the center of the central area 130 of the injection region 119, and the peripheral injection holes 137 and 137′ are disposed around the central injection hole 132. Preferably, the peripheral injection holes 137 and 137′ are located along a plurality of circles whose centers coincide with the center of the central injection hole 132. For example, a set of first peripheral injection holes 137 are located and spaced from one another along a first circle whose center coincides with that of the central injection hole 132, and a set of second peripheral injection holes 137′ are located and spaced from one another along a second circle whose center also coincides with that of the central injection hole 132. The radius of the second circle is large than that of the first circle. Also, the central injection hole 132 and respective peripheral injection holes 137, 137′ are arranged in groups in each of which the injection holes are aligned in a respective diametrical direction of the circles (simply referred to hereinafter as “a diametrical direction”). For example, the injection holes 132, 137 and 137′ of one such group are aligned in a diametrical direction corresponding to line III-III′ in FIG. 9.

The central injection hole 132 has a center injection hole inlet 133a and a center injection hole outlet 133b. The center injection hole inlet 133a is contiguous with the internal passageway of the gas injection pipe 120, and the center injection hole outlet 133b forms an opening at the outside of the gas injection pipe 120. Similarly, the first and second peripheral injection holes 137 and 137′ include first and second peripheral injection hole inlets 138a and 138a′, and first and second peripheral injection hole outlets 138b and 1138b′, respectively. The first and second peripheral injection hole inlets 138a and 138a′ are contiguous with the internal passageway of the gas injection pipe 120, and the first and second peripheral injection hole outlets 138b and 138b′ form openings at the outside of the gas injection pipe 120.

The widths of the central, first and second injection holes 132, 137 and 137′ gradually increase from the center, first and second injection hole inlets 133a, 138a and 138a′ to the center, first and second injection hole outlets 133b, 138b and 138b′, respectively. That is, the center, first and second injection hole inlets 133a, 138a and 138a′ are narrower than the center, first and second injection hole outlets 133b, 138b and 138b′, respectively.

Each of the injection holes 132, 137 and 137′ has an imaginary axis 134, 139 and 139′ lying in a plane that intersects the other injection holes aligned therewith in the diametrical direction. The imaginary axes 134, 139 and 139′ also extend from a center of the internal passageway of the gas injection pipe 120 through the centers of the injection holes 132, 137 and 137′, respectively (through the geometric center of the area located midway between the inlet and outlet thereof, as well as through the centers of the inlet and outlet thereof). Each imaginary axis 134, 139 and 139′ thus represents the direction of inclination or taper of the injection hole 132, 137′ and 137′. Preferably, the imaginary axis 134 of the central injection hole 132 is parallel to an imaginary axis 140 perpendicular to that portion of the sidewall of the gas injection pipe 120 having the injection region 119. Also, preferably, the imaginary axes 139 and 139′ of the first and second peripheral injection holes 137 and 137′ subtend predetermined first and second angles Θ and Θ′ with the imaginary vertical axis 140, respectively. In this case, the first angle Θ is preferably smaller than the second angle Θ′. That is, the first peripheral injection holes 137 incline in a direction inwardly toward the central injection hole 132 along the plane in which the injection holes 132, 137 and 137′ are aligned, and the second peripheral injection holes 137′ also incline in a direction inwardly toward the central injection hole 132 but in a more pronounced way than the first injection holes 137.

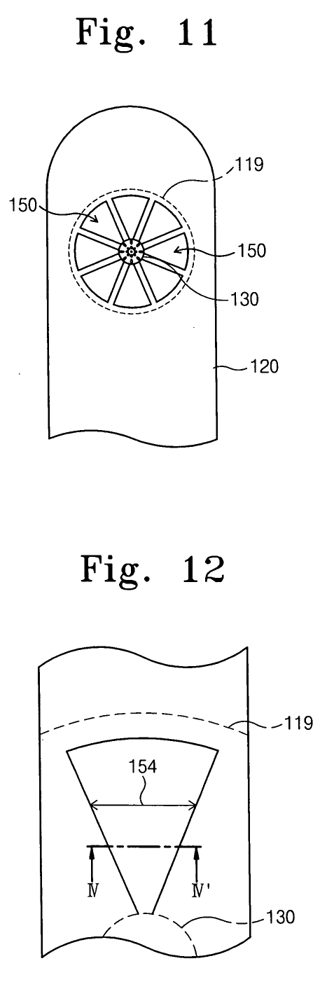

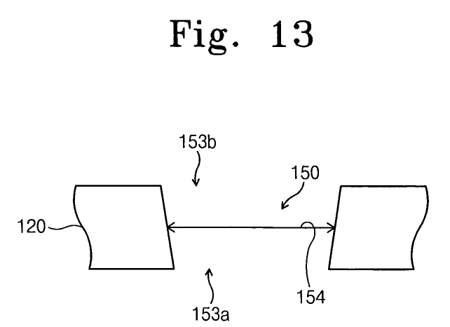

In other words, the inlets 138a of the first peripheral injection holes 137 are centered closer to the axis 134 than the outlets 138b of the first peripheral injection holes 137, respectively. Likewise, the inlets 138a′ of the second peripheral injection holes 137′ are centered closer to the axis 134 than the outlets 138b′ of the second peripheral injection holes 137′, respectively. However, this relative offset between the inlets and outlets 138a′ and 138b′ of the second peripheral injection holes 137′ in the diametrical direction is greater than the relative offset between the inlets and outlets 138a and 138b of the first peripheral injection holes 137 in the diametrical direction. For this reasons, namely, the inclined and tapered configurations of the injection holes 132, 137′ and 137′, the source gases are uniformly injected over the wafer 111 from the central portion 132 of the injection region 119, as well as from the injection slots 122. FIGS. 11 to 13 show another embodiment of a gas injection pipe 120 of a plasma chemical vapor deposition apparatus according to the present invention.

Referring to FIGS. 4, 11, 12 and 13, a plurality of injection slots 150 are located in the injection region 119 of the gas injection pipe 120. Preferably, the injection slots 150 radiate from a central area 130 of the injection region 119. The central area 130 is the same as that of the embodiment of the gas injection pipe of FIGS. 6 and 10. The injection slot 150 places the internal passageway of the gas injection pipe 120 parting communication with the interior of the process chamber 105.

The width 154 of the injection slot 150 gradually increases from one end of the injection slot 150 to the other end of the injection slot 150, i.e., in a direction from the central area 130 of the injection region 119 to the outer periphery of the injection region 119. That is, the injection slot 150 is fan-shaped. The end of the injection slot 150 adjacent the outer periphery of the injection region 119 may be arcuate. Preferably, the injection slots 150 are equi-angularly disposed about the center of the injection region 119. As a result, source gases are uniformly injected over the wafer 111 supported by the electrostatic chuck 1.

Each injection slot 150 has a slot inlet 153a and a slot outlet 153b. The width of the slot inlet 153a is smaller than that of the slot outlet 153b as taken at each location from the central area 130 of the injection region to the outer periphery of the injection region 119. In other words, both internal side wall surfaces of the gas injection pipe 120, which define the sidewalls of the injection slot 150, are sloped. The maximal width the slot inlet 153a is preferably 0.8 mm to 3.0 mm.

According to the plasma chemical vapor deposition apparatus of the present invention, as described above, the injection regions of the gas injection pipes each have a plurality of injection slots. Accordingly, the magnitude of the power supplied to the process chamber for producing plasma in the chamber is minimal in those portions of the gas injection pipes located in the chamber. As a result, the amount of residue formed in the gas injection pipes is minimal. Therefore, particle contamination of the wafer is also minimized and the plasma chemical vapor deposition apparatus does not have to be cleaned as frequently. Accordingly, the deposition process can be carried out with a high degree of productivity.

In addition, the injection slots radiate from a central area of the injection region, and the width of the slots gradually increases from the inlets to the outlets of the slots. Accordingly, the source gases are uniformly injected from the injection region over a wafer supported on a chuck within the process chamber.Furthermore, the quantity of source gas injected can be high, and uniformity of the injection of the source gases is enhanced because the central area of the injection region of the gas injection pipe has a plurality of injection holes.

Finally, although the present invention has been described in connection with the preferred embodiments thereof, these embodiments can be changed and modified without departing from the true spirit and scope of the present invention as defined by the following claims.

1. A plasma enhanced chemical vapor deposition apparatus comprising:
a process chamber;
an electrostatic chuck disposed in the process chamber, and dedicated to support a wafer; and
at least one gas injection pipe extending within the process chamber, each said gas injection pipe having a sidewall, an internal passageway, and an injection region from which source gases are injected into said process chamber from the internal passageway, wherein said gas injection pipe has a plurality of slots extending through said sidewall within the injection region.

2. The apparatus of claim 1, wherein each of said injection slots has an inlet contiguous with the internal passageway, and an outlet defining an opening at the exterior of the sidewall, and wherein the width of each of the injection slots increases from the inlet to the outlet thereof.

3. The apparatus of claim 1, wherein the injection slots radiate from a central area of the injection region.

4. The apparatus of claim 3, wherein the injection slots are equi-angularly disposed about the central area of the injection region.

5. The apparatus of claim 3, wherein each said at least one gas injection pipe has a plurality of injection holes extending through the sidewall thereof at said central area of the injection region.

6. The apparatus of claim 5, wherein each of the injection holes has an inlet contiguous with the internal passageway, and an outlet defining an opening at the exterior of the sidewall, and wherein the width of each of the injection holes increases from the inlet to the outlet thereof.

7. The apparatus of claim 5, wherein the injection holes include a central injection hole located at the center of said central area, a plurality of first peripheral injection holes disposed along of a first circle, and a plurality of second peripheral injection holes disposed along a second circle, the centers of said first and second circles each coinciding with the center of the central injection hole, and the second circle having a larger radius than the first circle,
each of the peripheral injection holes being inclined such that an imaginary axis passing through a center of the internal passageway of the injection pipe and the center of the peripheral injection hole subtends an angle with an imaginary axis that passes through said center of the internal passageway and the center of said central injection hole, and
the angles being subtended by the imaginary axes passing through the centers of the second peripheral injection holes being larger than the angles subtended by the imaginary axes passing through the centers of the first injection holes.

8. The apparatus of claim 1, wherein the width of each of the injection slots increases from one end of the injection slot to the other end of the injection slot.

9. The apparatus of claim 1, and further comprising:
plasma generating means for exciting gas injected into the process chamber form said at least one injection pipe to thereby produce plasma in the process chamber;
a first generator that supplies a first radio frequency power to the plasma generating means; and
a second generator that supplies a second radio frequency power to the electrostatic chuck.

10. A plasma enhanced chemical vapor deposition apparatus comprising:
a process chamber;
an electrostatic chuck disposed in the process chamber, and dedicated to support a wafer; and
at least one gas injection pipe extending within the process chamber, each said gas injection pipe having a sidewall, an internal passageway, and an injection region from which source gases are injected into said process chamber from the internal passageway, wherein said gas injection pipe has a plurality of slots extending through said sidewall within the injection region, the injection slots radiating from a central area of the injection region, and the width of the injection slot increasing in a direction from the central area of the injection region to the outer periphery of the injection region.

11. The apparatus of claim 10, wherein each of said injection slots has an inlet contiguous with the internal passageway, and an outlet defining an opening at the exterior of the sidewall, and wherein the width of each of the injection slots increases from the inlet to the outlet thereof.

12. The apparatus of claim 10, wherein the injection slots are equi-angularly disposed about the central area of the injection region.

13. The apparatus of claim 10, wherein each said at least one gas injection pipe has a plurality of injection holes extending through the sidewall thereof at said central area of the injection region.

14. The apparatus of claim 13, wherein each of the injection holes has an inlet contiguous with the internal passageway, and an outlet defining an opening at the exterior of the sidewall, and wherein the width of each of the injection holes increases from the inlet to the outlet thereof.

15. The apparatus of claim 13, wherein the injection holes include a central injection hole located at the center of said central area, a plurality of first peripheral injection holes disposed along of a first circle, and a plurality of second peripheral injection holes disposed along a second circle, the centers of said first and second circles each coinciding with the center of the central injection hole, and the second circle having a larger radius than the first circle,
each of the peripheral injection holes being inclined such that an imaginary axis passing through a center of the internal passageway of the injection pipe and the center of the peripheral injection hole subtends an angle with an imaginary axis that passes through said center of the internal passageway and the center of said central injection hole, and the angles being subtended by the imaginary axes passing through the centers of the second peripheral injection holes being larger than the angles subtended by the imaginary axes passing through the centers of the first injection holes.
